(19) United States
(12) Patent Application Publication
(10) Pub. No.: US 2009/0205783 A1
(43) Pub. Date: Aug. 20, 2009

(54) SUBSTRATE PROCESSING APPARATUS

(75) Inventors: Junichi TANABE, Toyama-shi (JP); Jie Wang, Toyama City (JP)

Correspondence Address: MATTINGLY & MALUR, P.C., 1800 DIAGONAL ROAD, SUITE 370, ALEXANDRIA, VA, 22314, US

(73) Assignee: Hitachi-Kokusai Electric Inc.

(21) Appl. No.: 12/372,304

(22) Filed: Feb. 17, 2009

(30) Foreign Application Priority Data
Feb. 20, 2008 (JP) 2008-038321
Jan. 20, 2009 (JP) 2009-010273

(51) Int. Cl. H01L 21/306; C23C 16/44

(52) U.S. Cl. 156/345.37; 118/724

(57) ABSTRACT

A substrate processing apparatus comprises a process chamber accommodating stacked substrates; a heating unit heating an inside of the process chamber to a predetermined temperature; a gas supply unit supplying predetermined process gas to the inside of the process chamber; and an exhaust unit exhausting the inside of the process chamber. The gas supply unit comprises: a gas supply nozzle having a straight pipe shape and installed in a stacked direction of the substrates; a metal pipe supporting the gas supply nozzle; and a manifold forming a lower part of the process chamber. The metal pipe comprises: a first part extending from an outside of the process chamber to the inside of the processes chamber through the manifold; and a second part connected to the first part and extending in the stacked direction of the substrates. The gas supply nozzle is fitted to and supported by the second part.

### CROSS-REFERENCE TO RELATED PATENT APPLICATION

This U.S. non-provisional patent application claims priority under 35 U.S.C. §119 of Japanese Patent Application Nos. 2008-038321, filed on Feb. 20, 2008, and 2009-010273, filed on Jan. 20, 2009, in the Japanese Patent Office, the entire contents of which are hereby incorporated by reference.

### BACKGROUND OF THE INVENTION

1. Field of the Invention

The present invention relates to a substrate processing apparatus for performing a process such as thin film formation by a chemical vapor deposition (CVD) method, impurity diffusion, annealing, and etching on a substrate such as a silicon wafer and a glass substrate.

2. Description of the Prior Art

As a substrate processing apparatus, there is a batch type substrate processing apparatus that can be used for processing a predetermined number of substrates at a time, and as a kind of batch type substrate processing apparatus, there is a vertical substrate processing apparatus having a vertical process furnace.

In a vertical decompression CVD apparatus, thin films are formed on the surfaces of wafers by placing the wafers horizontally in multiple stages in a quartz reaction tube forming a process chamber, decompressing the process chamber, introducing process gas into the process chamber while heating the process chamber using a heating device, and depositing activated process gas on the surfaces of the wafers.

A plurality of gas supply nozzles erected along the inner wall of the reaction tube are used to introduce process gas into the process chamber.

With reference to FIG. 12 and FIG. 13, an explanation will now be given on a structure for supporting gas supply nozzles in a conventional substrate processing apparatus.

A cylindrical quartz reaction tube 1 having an opened side is erected on a cylindrical metal manifold 2, and a lower opening of the manifold 2 forms a furnace port 3. A wafer 4 is charged into the reaction tube 1 through the furnace port 3, and the furnace port 3 is configured to be air-tightly closed by a furnace port cover (not shown).

Each gas supply nozzle 5 includes a vertical part 6 extending upward along the inner wall of the reaction tube 1 and a horizontal part 7 extending horizontally from a lower end of the vertical part 6. The horizontal part 7 penetrates the manifold 2 in a radial direction of the manifold 2, and a protruded end of the horizontal part 7 is connected to a process gas supply pipe 8.

A vertical load acting on the gas supply nozzle 5 is supported by a nozzle support part 9 described hereinafter.

A ledge part 11 is protruded inwardly from the inner surface of the manifold 2, and a nozzle support screw 12 is screwed through the ledge part 11 in a vertical direction. A disk-shaped nozzle seat 13 is installed on an upper end of the nozzle support screw 12 for making contact with the horizontal part 7.

The height of the nozzle seat 13 can be adjusted using the nozzle support screw 12, and by bringing the nozzle seat 13 into contact with the horizontal part 7, a load caused by the weight of the gas supply nozzle 5 can be transmitted to the ledge part 11 through the horizontal part 7 and the nozzle support screw 12 so that the horizontal part 7 can be free from the load caused by the weight of the gas supply nozzle 5.

In addition, as shown in FIG. 12, a plurality of tubular nozzle holders 14 are protruded at the manifold 2 in radial directions of the manifold 2 and arranged at a predetermined angular pitch for preventing interference. Screws 15 are formed on outer ends of the nozzle holders 14, and pipe joints 16 are coupled to the screws 15.

The horizontal part 7 penetrates the nozzle holder 14 and is air-tightly connected to the process gas supply pipe 8 by fastening the pipe joint 16 to compress an O-ring 17 disposed among the nozzle holder 14, the horizontal part 7, and the process gas supply pipe 8.

In the conventional structure for supporting the gas supply nozzle 5, the horizontal part 7 is supported through the O-ring 17, and the sealing between the horizontal part 7 and the process gas supply pipe 8 is dependent on the compressed state of the O-ring 17. Thus, if the sealing by the O-ring 17 is insufficient, process gas may undesirably leak through a connection part of the gas supply nozzle 5. In addition, a holding force acting horizontally on the horizontal part 7 is a frictional force acting between the horizontal part 7 and the O-ring 17 and dependent on the compressed state of the O-ring 17.

Therefore, a large load acts on the horizontal part 7 due to the coupling force between the process gas supply pipe 8 and the pipe joint 16, and there is a possibility of breakage of the horizontal part 7 because the adjustment of the coupling force between the process gas supply pipe 8 and the pipe joint 16 is an ambiguous work.

In addition, since the outer diameter of the nozzle holder 14 is greater than the outer diameter of the process gas supply pipe 8 into which the horizontal part 7 is inserted, the outer diameter of the pipe joint 16 is large, and the angular pitch between the nozzle holders 14 is large. In this case, since the nozzle holders 14 are installed in a limited region, the number of the nozzle holders 14 (that is, the number of the gas supply nozzles 5) is limited.

### SUMMARY OF THE INVENTION

An object of the present invention is to provide a substrate processing apparatus configured to prevent leakage of process gas through a connection part of a gas supply nozzle and allow each attachment of the gas supply nozzle with less possibility of breakage of the gas supply nozzle.

According to an aspect of the present invention, there is provided a substrate processing apparatus comprising: a process chamber configured to accommodate substrates in a stacked manner; a heating unit configured to heat an inside of the process chamber to a predetermined temperature; a gas supply unit configured to supply predetermined process gas to the inside of the process chamber; and an exhaust unit configured to exhaust the inside of the process chamber, wherein the gas supply unit comprises: a gas supply nozzle having a straight pipe shape and installed in a stacked direction of the substrates; a metal pipe configured to support the gas supply nozzle; and a manifold forming a lower part of the process chamber, wherein the metal pipe comprises: a first part extending from an outside of the process chamber to the inside of the processes chamber through the manifold; and a second part connected to the first part and extending in the stacked direction of the substrates, wherein the gas supply nozzle is fitted to the second part and supported by the second part.

### BRIEF DESCRIPTION OF THE DRAWINGS

FIG. 1 is a side sectional view illustrating a substrate processing apparatus according to an embodiment of the present invention.

FIG. 2 is a cross sectional view illustrating the substrate processing apparatus according to an embodiment of the present invention.

FIG. 3 is a side sectional view illustrating a process furnace of the substrate processing apparatus and the surroundings of the process furnace according to an embodiment of the present invention.

FIG. 4 is a side sectional view illustrating the process furnace according to a first embodiment of the present invention.

FIG. 5 is a side sectional view illustrating the process furnace according to a second embodiment of the present invention.

FIG. 6 is a cross sectional view illustrating the process furnace according to the second embodiment of the present invention.

FIG. 7 is a side sectional view illustrating the process furnace according to a third embodiment of the present invention.

FIG. 8 is a side sectional view illustrating the process furnace according to a fourth embodiment of the present invention.

FIG. 9 is a side sectional view illustrating the process furnace according to a fifth embodiment of the present invention.

FIG. 10 is a partial perspective view illustrating a connection part according to a sixth embodiment of the present invention.

FIG. 11 is a partial sectional view illustrating the connection part according to the sixth embodiment of the present invention.

FIG. 12 is a schematic cross sectional view illustrating quartz nozzles attached to a manifold in a conventional substrate processing apparatus.

FIG. 13 is a schematic side sectional view illustrating the quartz nozzle attached to the manifold in the conventional substrate processing apparatus.

### DETAILED DESCRIPTION OF THE PREFERRED EMBODIMENTS

Embodiments of the present invention will be described hereinafter with reference to the attached drawings.

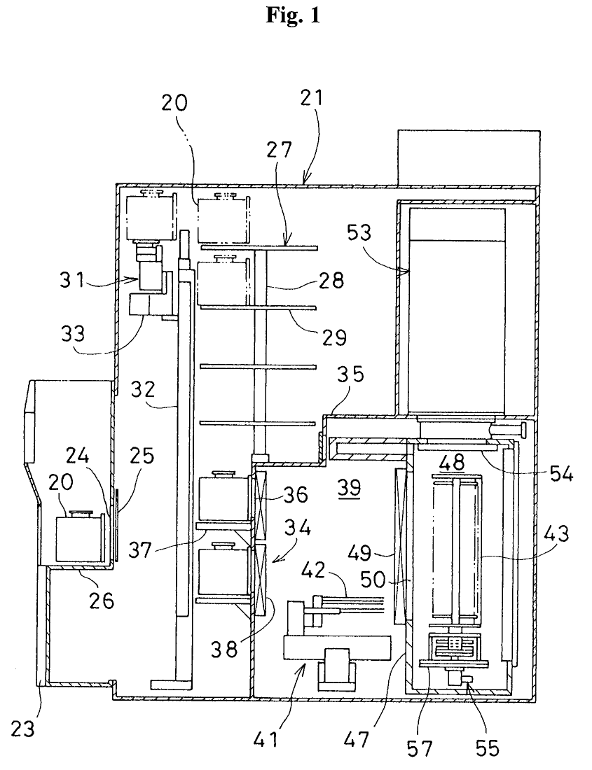

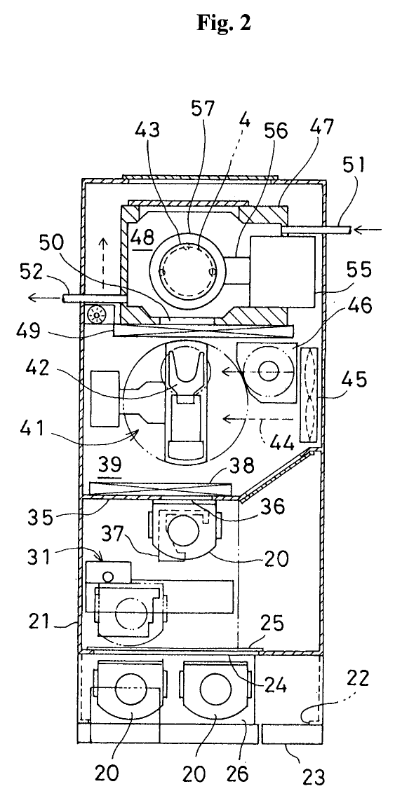

FIG. 1 and FIG. 2 illustrate an exemplary substrate processing apparatus for implementing the present invention.

In FIG. 1 and FIG. 2, reference numeral 21 denotes a housing, and a front maintenance port 22 is installed at the front side of the housing 21 for maintenance works, and a front maintenance door 23 is used to close and open the front maintenance port 22.

At the front wall of the housing 21, a substrate container carrying port 24 is installed, and a front shutter 25 is used to close and open the substrate container carrying port 24. Near the substrate container carrying port 24, a substrate container stage 26 is installed, and at the substrate container stage 26, a substrate container (hereinafter, referred to as a pod 20) is placed and adjusted in orientation.

Substrates made of a material such as silicon (hereinafter, the substrates will be referred to as wafers 4) are carried in a state where the wafers 4 are charged in the pod 20. The pod 20 is an airtight container having an openable cover.

The pod 20 is configured to be carried onto and away from the substrate container stage 26 by an in-process carrying device (not shown).

Near the upper part of the center of the housing 21 in a front-to-back direction, a rotary type container keeping device 27 is installed, and a plurality of pods 20 can be stored at the container keeping device 27.

The container keeping device 27 includes a post 28 vertically installed for being intermittently rotated, and a plurality of disk-shaped shelf plates 29 vertically arranged in four stages and supported by the post 28. Each of the shelf plates 29 can hold a plurality of pods 20.

In the housing 21, a pod carrying device 31 is installed between the substrate container stage 26 and the container keeping device 27. The pod carrying device 31 includes a container lift mechanism (hereinafter, referred to as a pod elevator 32) capable of moving a pod 20 upward and downward, and a pod carrying mechanism 33 capable of moving a pod 20 forward, backward, leftward, and rightward. By cooperative operations of the pod elevator 32 and the pod carrying mechanism 33 of the pod carrying device 31, a pod 20 can be carried among the substrate container stage 26, the container keeping device 27, and pod openers 34 (described later).

At the rear lower part of the inside of the housing 21, a sub housing 35 is installed, and at the front wall of the sub housing 35, a pair of substrate carrying ports 36 are installed in a vertical two-stage arrangement for carrying wafers 4 into and out of the sub housing 35. The pod openers 34 are installed at the substrate carrying ports 36, respectively.

Each of the pod openers 34 includes a stage 37 for placing a pod 20 thereon, and a cover attachment/detachment mechanism 38 for attachment and detachment of the cover of the pod 20. As the cover of the pod 20 placed on the stage 37 is attached or detached by the cover attachment/detachment mechanism 38, the substrate carrying port 36 is closed or opened.

A transfer chamber 39 formed by the sub housing 35 is fluidically isolated from a space where the pod carrying device 31 and the container keeping device 27 are installed. In the front region of the transfer chamber 39, a wafer transfer mechanism 41 is installed. The wafer transfer mechanism 41 includes a set of substrate holders 42 for placing wafers 4. The substrate holders 42 are configured to be rotated or linearly moved in a horizontal direction, or moved upward and downward. wafers 4 can be charged into and discharged from a substrate holding device (hereinafter, referred to as a boat 43) by the wafer transfer mechanism 41.

As shown in FIG. 2, a cleaning unit 45 is installed at the right part of the transfer chamber 39, and the cleaning unit 45 includes a supply fan for supplying clean atmosphere or clean air (inert gas) 44 and a dust filer. Between the wafer transfer mechanism 41 and the cleaning unit 45, a notch aligning device 46 is installed as a substrate aligning device for aligning the circumferential direction of a wafer 4.

Clean air 44 blown by the cleaning unit 45 flows along the notch aligning device 46 and the wafer transfer mechanism 41 and is then sucked through a duct (not shown).

In the rear region of the transfer chamber 39, an airtight pressure-resistant housing 47 is installed, which can be kept at a lower pressure (hereinafter, referred to as a negative pressure) than atmospheric pressure. The pressure-resistant housing 47 forms a loadlock chamber 48 in which the boat 43 can be accommodated.

At the front wall of the pressure-resistant housing 47, a wafer carrying opening 50 is formed, and the wafer carrying opening 50 is configured to be opened and closed by a gate valve 49. A gas supply pipe 51 is connected to a sidewall of the pressure-resistant housing 47 for supplying nitrogen gas to the loadlock chamber 48, and an exhaust pipe 52 is connected to a sidewall of the pressure-resistant housing 47 for creating a negative pressure in the loadlock chamber 48.

A process furnace 53 is installed at the upside of the loadlock chamber 48, and a furnace port 3 (refer to FIG. 13) of the process furnace 53 is configured to be closed and opened by a furnace port gate valve 54.

At the loadlock chamber 48, a substrate holder lift mechanism (hereinafter, referred to as boat elevator 55) is installed for moving the boat 43 upward and downward. At a lift arm 56 connected to the boat elevator 55, a seal cap 57 is installed as a cover, and the seal cap 57 is configured to seal the furnace port 3 air-tightly.

The boat 43 is made of a heat-resistant material not contaminating a wafer 4, such as quartz or silicon carbide. The boat 43 is configured to hold a plurality of wafers 4 horizontally (for example, about 50 to 125 wafers).

Next, an operation of the substrate processing apparatus will be explained.

When a pod 20 is placed on the substrate container stage 26, the front shutter 25 is moved to open the substrate container carrying port 24, and then the pod carrying device 31 carries the pod 20 into the housing 21 through the opened substrate container carrying port 24.

The pod 20 carried into the housing 21 may be automatically carried onto a predetermined one of the shelf plates 29 of the container keeping device 27 and transferred from the shelf plate 29 to one of the stages 37 by the pod carrying device 31 after the pod 20 is temporarily stored on the shelf plate 29; or the pod 20 carried into the housing 21 may be directly transferred to the stage 37. At this time, the substrate carrying port 36 is closed by the cover attachment/detachment mechanism 38 of the pod opener 34, and the transfer chamber 39 is fully filled with clean air 44. For example, nitrogen gas is fully filled in the transfer chamber 39 as the clean air 44 to keep the oxygen concentration of the inside of the transfer chamber 39 equal to or lower than 20 ppm, that is, to keep the oxygen concentration of the inside of the transfer chamber 39 much lower than the oxygen concentration of the inside (air atmosphere) of the housing 21.

In a state where the end face of a wafer opening of the pod 20 placed on the stage 37 is pressed by the periphery of the substrate carrying port 36, the cover of the pod 20 is removed by the cover attachment/detachment mechanism 38 so that the wafer opening of the pod 20 can be opened. In addition, the wafer carrying opening 50 of the loadlock chamber 48 which is previously kept at atmospheric pressure is opened by operating the gate valve 49.

After the wafer transfer mechanism 41 picks up a wafer 4 from the pod 20 through the wafer opening of the pod 20 and aligns the wafer 4 using the notch aligning device 46, the wafer transfer mechanism 41 carries the wafer 4 into the loadlock chamber 48 through the wafer carrying opening 50 and transfers the wafer 4 to the boat 43 for charging the wafer 4 in the boat 43. After the wafer transfer mechanism 41 transfers the wafer 4 to the boat 43, the wafer transfer mechanism 41 returns to the pod 20 for charging the next wafer 4 from the pod 20 to the boat 43.

At the same time when wafers 4 are charged into the boat 43 from a pod 20 placed on one of the pod openers 34 (the upper or lower pod opener 34), another pod 20 is carried onto the other of the pod openers 34 (the lower or upper pod opener 34) from the container keeping device 27 or the substrate container stage 26 by the pod carrying device 31, and the wafer opening of which is opened by the pod opener 34.

After a predetermined number of wafers 4 are charged into the boat 43, the wafer carrying opening 50 is closed by the gate valve 49, and the inside of the loadlock chamber 48 is decompressed by evacuation through the exhaust pipe 52.

After the inside of the loadlock chamber 48 is decompressed to the same pressure as the inside pressure of the process furnace 53, the furnace port 3 is opened by operating the furnace port gate valve 54.

Next, the seal cap 57 is lifted by the boat elevator 55 to load the boat 43 into the process furnace 53.

After the boat 43 is fully loaded into the process furnace 53, the furnace port 3 is air-tightly sealed by the seal cap 57, and a desired process is performed on the wafers 4 in the process furnace 53.

After the wafers 4 are processed, the boat 43 is unloaded from the process furnace 53 by the boat elevator 55, and the gate valve 49 is opened after returning the inside pressure of the pressure-resistant housing 47 to atmospheric pressure. Thereafter, the wafers 4 and the pod 20 are carried out of the housing 21 approximately in the reverse order except for the alignment of the wafers 4 using the notch aligning device 46.

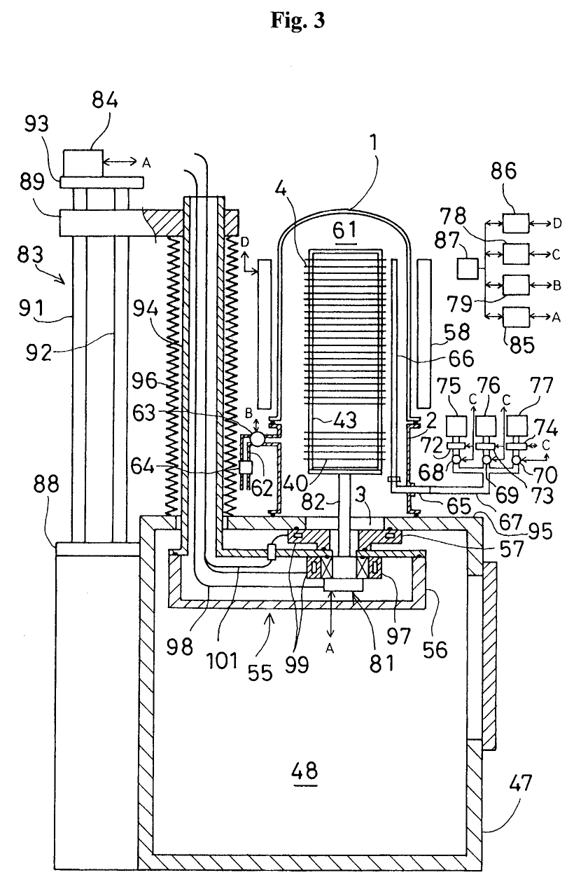

FIG. 3 illustrates an example of the process furnace 53 of the substrate processing apparatus and the surroundings structure of the process furnace 53.

The process furnace 53 includes a heater 58 as a heating unit. The heater 58 has a cylindrical shape and is configured by a heating wire and a heat-resistant material part installed around the heating wire. The heater 58 is supported on a holder (not shown) in a manner such that the heater 58 is coaxial with a reaction tube 1.

In the center part of the heater 58, the reaction tube 1 is installed coaxial with the heater 58. The reaction tube 1 is made of a heat-resistant material such as quartz (SiO₂) or silicon carbide (SiC). The reaction tube 1 has a cylindrical shape with a closed top side and an opened bottom side. The reaction tube 1 forms a process chamber 61 and can accommodate wafers 4 held in the boat 43.

At the bottom side of the reaction tube 1, a manifold 2 is installed coaxial with the reaction tube 1. For example, the manifold 2 is made of stainless steel and has a cylindrical shape with opened top and bottom sides. The reaction tube 1 is erected on the manifold 2. In addition, an O-ring is installed between the manifold 2 and the reaction tube 1 as a seal member for sealing between the manifold 2 and the reaction tube 1.

The manifold 2 is supported by a holder (not shown) so that the reaction tube 1 can be kept in an upright position. A reaction vessel is constituted by the reaction tube 1 and the manifold 2.

A gas exhaust pipe 62 is connected to the manifold 2, and a vacuum exhaust device 64 such as a vacuum pump is connected to the downstream side of the gas exhaust pipe 62 through a pressure sensor (not shown) and an automatic pressure controller (APC) valve 63.

In addition, a nozzle holder 65 is installed through the manifold 2, and a gas supply nozzle 66 is vertically supported by the nozzle holder 65. The nozzle holder 65 is connected to a gas supply system 67, and process gas necessary for film formation is supplied from the gas supply system 67. According to the kinds of films, the gas supply system 67 provides different process gases.

For example, in the case where a silicon film is formed by a selective epitaxial growth method, process gases such as H₂, SiH₄, Cl₂, and N₂ may be supplied, and in the case where a silicon germanium film is formed by a selective epitaxial growth method, process gases such as H₂, SiH₄, GeH₄, HCl, and N₂ may be supplied. That is, various gases may be supplied in combination according to the kinds of films to be formed.

The upstream side of the gas supply system 67 is divided into three parts, and first to third gas supply sources 75, 76, and 77 are connected to the three parts through valves 68, 69, and 70, and mass flow controllers (MFCs) 72, 73, and 74 used as gas flow rate control devices.

A gas flow rate control unit 78 is electrically connected to the MFCs 72, 73, and 74, and the valves 68, 69, and 70, so as to supply desired amounts of process gases at desired times.

The APC valve 63 and the pressure sensor (not shown) are electrically connected to a pressure control unit 79 so that the pressure control unit 79 can control the size of an opening of the APC valve 63 based on a pressure detected by the pressure sensor to adjust the inside pressure of the process chamber 61 to a desired level at a desired time.

At the seal cap 57, a rotary mechanism 81 is installed. A rotation shaft 82 of the rotary mechanism 81 is connected to the boat 43 through the seal cap 57 to rotate the wafers 4 by rotating the boat 43.

The seal cap 57 is supported by the lift arm 56 and configured to be raised and lowered by the boat elevator 55. The lift arm 56 is connected to a lift mechanism 83 installed outside the pressure-resistant housing 47 and is configured to be raised and lowered in a vertical direction by a lift motor 84 of the lift mechanism 83.

A driving control unit 85 is electrically connected to the rotary mechanism 81 and the lift motor 84 to control a predetermined operation at a desired time.

At a lower part of the boat 43, a plurality of disk-shaped heat resistant members such as heat-resistant plates 40 made of a heat-resistant material such as quartz or silicon carbide are horizontally oriented in multiple stages in order to prevent heat transfer from the heater 58 to the manifold 2.

Near the heater 58, a temperature sensor (not shown) is installed to measure the temperature inside the process chamber 61. The heater 58 and the temperature sensor are electrically connected to a temperature control unit 86 so that the inside temperature of the process chamber 61 can be maintained at a desired temperature distribution at a desired time by controlling the power condition of the heater 58 based on temperature information detected by the temperature sensor.

The gas flow rate control unit 78, the pressure control unit 79, the driving control unit 85, and the temperature control unit 86 constitute an manipulation unit and an input/output unit and are electrically connected to a main control unit 87 used to control the overall operation of the substrate processing apparatus.

First process gas is supplied from the first gas supply source 75, and after the flow rate of the first process gas is controlled by the MFC 72, the first process gas is introduced into the process chamber 61 by the gas supply nozzle 66 through the valve 68. Second process gas is supplied from the second gas supply source 76, and after the flow rate of the first process gas is controlled by the MFC 73, the second process gas is introduced into the process chamber 61 by the gas supply nozzle 66 through the valve 69. Third process gas is supplied from the third gas supply source 77, and after the flow rate of the first process gas is controlled by the MFC 74, the third process gas is introduced into the process chamber 61 by the gas supply nozzle 66 through the valve 70. The process gases are discharged from the process chamber 61 through the gas exhaust pipe 62 by the vacuum exhaust device 64.

The boat elevator 55 and the lift mechanism 83 will now be described in more detail.

A lower base 88 is installed at an outer side of a pressure-resistant housing 47. A guide shaft 91 slidably inserted in a lift plate 89 and a ball screw 92 coupled to the lift plate 89 are erected on the lower base 88. An upper base 93 is installed on the upper ends of the guide shaft 91 and the ball screw 92. By rotating the ball screw 92 using the lift motor 84 installed on the upper base 93, the lift plate 89 can be moved upward or downward.

At the lift plate 89, a hollow lift shaft 94 is installed to be extended from the lift plate 89. The lift shaft 94 is configured to be moved upward and downward together with the lift plate 89, and the connection part between the lift plate 89 and the lift shaft 94 is air-tightly sealed. The lift shaft 94 is movably inserted through a top plate 95 of the pressure-resistant housing 47, and a penetration hole of the top plate 95 through which the lift shaft 94 is inserted is sufficiently large such that the lift shaft 94 can be prevented from making contact with the top plate 95.

Between the pressure-resistant housing 47 and the lift plate 89, a bellows 96 is installed to enclose the periphery of the lift shaft 94 air-tightly. The bellows 96 is flexible and air-tightly seals parts through which the lift shaft 94 is inserted. The bellows 96 can be sufficiently expanded and contracted in accordance with lifting motions of the lift plate 89, and the bellows 96 has an inner diameter sufficiently greater than the outer diameter of the lift shaft 94 so as not to make contact with the lift shaft 94 during expansion or contraction.

The lift arm 56 is horizontally fixed to a lower end of the lift shaft 94. The lift arm 56 has an airtight hollow structure, and the rotary mechanism 81 is accommodated in the lift arm 56. A bearing part of the rotary mechanism 81 is cooled by a cooling mechanism 97. On the top surface of the lift arm 56, the seal cap 57 is air-tightly installed.

A power cable 98 is connected from an upper end of the lift shaft 94 to the rotary mechanism 81 through the hollow inside of the lift shaft 94. In addition, cooling passages 99 are formed in the cooling mechanism 97 and the seal cap 57, and coolant conduits 101 are connected to the cooling passages 99 for supplying cooling water. The coolant conduits 101 are connected to an external cooling water source through the hollow inside of the lift shaft 94.

As the ball screw 92 rotates upon the operation of the lift motor 84, the lift arm 56 is lifted together with the lift plate 89 and the lift shaft 94.

As the lift arm 56 is lifted, the furnace port 3 is closed by the seal cap 57, and in this state, wafer processing is possible. By lowering the lift arm 56, both the seal cap 57 and the boat 43 can be moved down to carry the wafers 4 to the outside.

Next, an explanation will be given on a method of forming an epitaxial silicon-germanium (Epi-SiGe) film on a substrate such as a wafer 4 as an example of a semiconductor device manufacturing process using the above-described process furnace 53. In the following description, each part of the substrate processing apparatus is controlled by the main control unit 87.

After a predetermined number of wafers 4 are charged into the boat 43, the boat 43 is lifted by the boat elevator 55 and loaded into the process chamber 61, and the furnace port 3 is air-tightly closed by the seal cap 57.

The inside of process chamber 61 is evacuated by the vacuum exhaust device 64 to a desired pressure (vacuum degree). At this time, the pressure inside the process chamber 61 is measured with the pressure sensor, and the APC valve 63 is feedback controlled based on the measured pressure. In addition, the inside of the process chamber 61 is heated by the heater 58 to a desired temperature. At this time, power to the heater 58 is feedback controlled based on temperature information detected by the temperature sensor so as to obtain desired temperature distribution in the process chamber 61. Thereafter, the rotary mechanism 81 rotates the boat 43 in which the wafers 4 are charged.

SiH₄ or Si₂H₆, GeH₄, and H₂, which are filled as process gases in the first gas supply source 75, the second gas supply source 76, and the third gas supply source 77, are supplied to the inside of the process chamber 61. To obtain desired flow rates of the process gases, openings of the MFCs 72, 73, and 74 are adjusted, and then the valves 68, 69, and 70 are opened to introduce the process gases into the process chamber 61 from the upper part of the process chamber 61 through the gas supply nozzle 66. In the process chamber 61, the process gases flow downward and are discharged from the process chamber 61 through the gas exhaust pipe 62. While the process gases pass through the process chamber 61, the process gases make contact with the wafers 4 so that Epi-SiGe films can be deposited on the surfaces of the wafers 4.

After a predetermined time passed, inert gas is supplied from an inert gas supply source (not shown) to replace the inside atmosphere of the process chamber 61 with the inert gas, and at the same time, the pressure inside the process chamber 61 returns to atmospheric pressure.

Thereafter, the boat elevator 55 lowers the lift arm 56 to move the seal cap 57 downward and open the furnace port 3, and the boat 43 in which the processed wafers 4 are held is unloaded from the reaction tube 1. Then, the processed wafers 4 are discharged from the boat 43 by the wafer transfer mechanism 41.

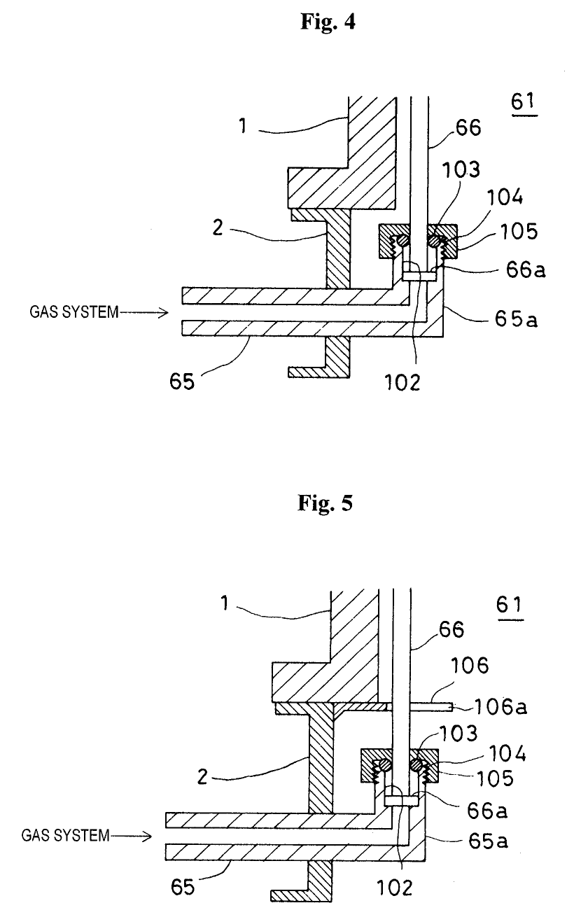

Next, a first embodiment of the present invention will be described with reference to FIG. 4.

A gas supply unit is constituted by the gas supply nozzle 66 and a support structure for the gas supply nozzle 66. The gas supply unit will now be described in detail with reference to FIG. 4.

For example, the gas supply nozzle 66 is a straight-pipe nozzle made of quartz, and a flange part 66a is formed on the lower end of the gas supply nozzle 66 as a stopper. If the gas supply nozzle 66 is sufficiently thick, the flange part 66a may be omitted.

The nozzle holder 65 is an elbow-shaped hollow metal pipe inserted through the manifold 2 in a radial direction (horizontal direction). The manifold 2 and the nozzle holder 65 are integrally united by air-tightly fixing the nozzle holder 65 to the manifold 2 by, for example, welding. An inner end part (second part) 65a of the nozzle holder 65 is upwardly bent at a right angle from a horizontal part (first part) of the nozzle holder 65, and the top side of the inner end part 65a is opened. In addition, the center axis of the inner end part 65a is parallel with the center axis of the reaction tube 1.

A nozzle hold hole 102 is bored in the inner end part 65a from the top side of the inner end part 65a in a manner such that the nozzle hold hole 102 is coaxial with the inner end part 65a; the diameter of the nozzle hold hole 102 is greater than the inner diameter of the nozzle holder 65 and substantially equal to the outer diameter of the flange part 66a; and a stepped part is formed at the lower end of the nozzle hold hole 102.

The top edge of the nozzle hold hole 102 is chamfered (rounded), and an O-ring 103 (a seal member) is pressed against the chamfered part. The outer surface of the upper end part of the inner end part 65a is threaded to form a screw part 104, and a ring nut 105 is coupled to the screw part 104.

When the lower end part of the gas supply nozzle 66 is inserted into the nozzle hold hole 102, the vertical position of the gas supply nozzle 66 is determined because the flange part 66a is brought into contact with the stepped part of the nozzle hold hole 102, and the radial (horizontal) position of the gas supply nozzle 66 is determined because the flange part 66a is fitted into the nozzle hold hole 102.

Since the ring nut 105 is screw-coupled to the inner end part 65a of the nozzle holder 65 with the O-ring 103 being disposed therebetween, the O-ring 103 is compressed between the chamfered part of the nozzle hold hole 102 and the gas supply nozzle 66 so that the nozzle holder 65 and the gas supply nozzle 66 can be air-tightly connected. Furthermore, between upper and lower two points, that is, between the flange part 66a and the O-ring 103, the gas supply nozzle 66 is held coaxial with the inner end part 65a, that is, the gas supply nozzle 66 is vertically held.

In addition, since the connection part between the nozzle holder 65 and the gas supply nozzle 66 is lower than the heater 58 installed around the reaction tube 1, the O-ring 103 can be less affected by thermal load.

In addition, the gas supply nozzle 66 can be precisely connected to the inner end part 65a without having to align the gas supply nozzle 66 in vertical, horizontal, and oblique directions. Therefore, the inner end part 65a, the ring nut 105, and the O-ring 103 can function as support parts for the gas supply nozzle 66 and pipe joints for the gas supply nozzle 66. Furthermore, the connection part between the nozzle holder 65 and the gas supply nozzle 66 is disposed inside the process chamber 61.

Therefore, leakage of process gas through the connection part between the nozzle holder 65 and the gas supply nozzle 66 can be prevented. Even when process gas leaks through the connection part between the nozzle holder 65 and the gas supply nozzle 66, the leaking process gas can be safely discharged from the process chamber 61 by using the vacuum exhaust device 64 because the leakage of the process gas occurs in the process chamber 61.

In addition, since a part of the nozzle holder 65 attached to the gas supply nozzle 66 is located inside the process chamber 61, attachment of the gas supply nozzle 66 can be carried out only in the process chamber 61. This allows arrangement of process gas pipes along the inner circumference of the process chamber 61. Therefore, as compared with the case of a conventional substrate processing apparatus, more process gas pipes can be installed, and thus process gas can be supplied to more positions or more kinds of process gases can be used in one apparatus.

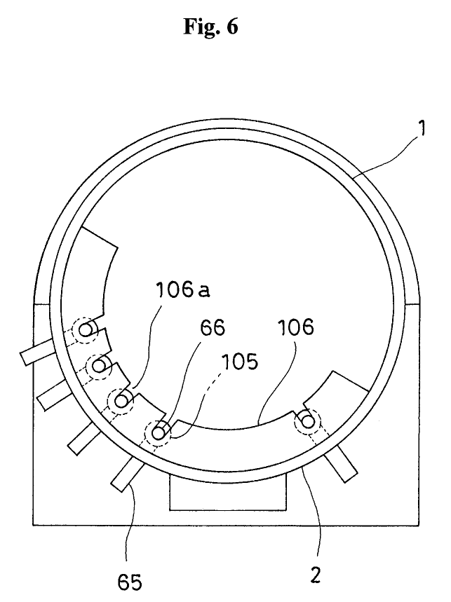

Next, a second embodiment of the present invention will be described with reference to FIG. 5 and FIG. 6.

In the second embodiment, a heat shield plate 106 is installed at the upside of the connection part between the nozzle holder 65 and the gas supply nozzle 66.

The heat shield plate 106 may be a semicircular ring shaped metal plate made of the same material as the manifold 2, for example, stainless steel. The outer periphery of the heat shield plate 106 is fixed to the inner wall of the manifold 2 by, for example, welding. As long as the heat shield plate 106 has a size suitable for covering the connection part between the nozzle holder 65 and the gas supply nozzle 66, the heat shield plate 106 can be a metal plate having any shape such as a complete ring shape, or the heat shield plate 106 can be locally installed at each gas supply nozzle 66.

In addition, so as to remove the ring nut 105 freely, the heat shield plate 106 is installed at a height where the distance between the bottom surface of the heat shield plate 106 and the top end surface of the inner end part (second part) 65a of the nozzle holder 65 is greater than the height of the ring nut 105.

In addition, slit(s) 106a having substantially the same diameter as the outer diameter of the gas supply nozzle 66 is formed in the heat shield plate 106 in a direction toward the center of the heat shield plate 106, and the inner end of the slit 106a is opened. The length of the slit 106a covers the distance from the center of the inner end part 65a of the nozzle holder 65 to the inner end of the heat shield plate 106. The gas supply nozzle 66 can be detached from the nozzle holder 65 by releasing the ring nut 105 from the state shown in FIG. 5, pulling the gas supply nozzle 66 in an upward direction, and moving the center axis of the gas supply nozzle 66 along the slit 106a. On the other hand, the gas supply nozzle 66 can be attached to the nozzle holder 65 in the reverse order of the detachment.

During a substrate treatment process, since radiant heat from the inside of the process chamber 61 to the connection part between the nozzle holder 65 and the gas supply nozzle 66 is blocked by the heat shield plate 106, the connection part between the nozzle holder 65 and the gas supply nozzle 66 is not directly heated by heat transferred from the inside of the process chamber 61.

Therefore, the connection part between the nozzle holder 65 and the gas supply nozzle 66 is not overheated, and the O-ring 103 used to connect the nozzle holder 65 and the gas supply nozzle 66 air-tightly can be less affected by thermal load.

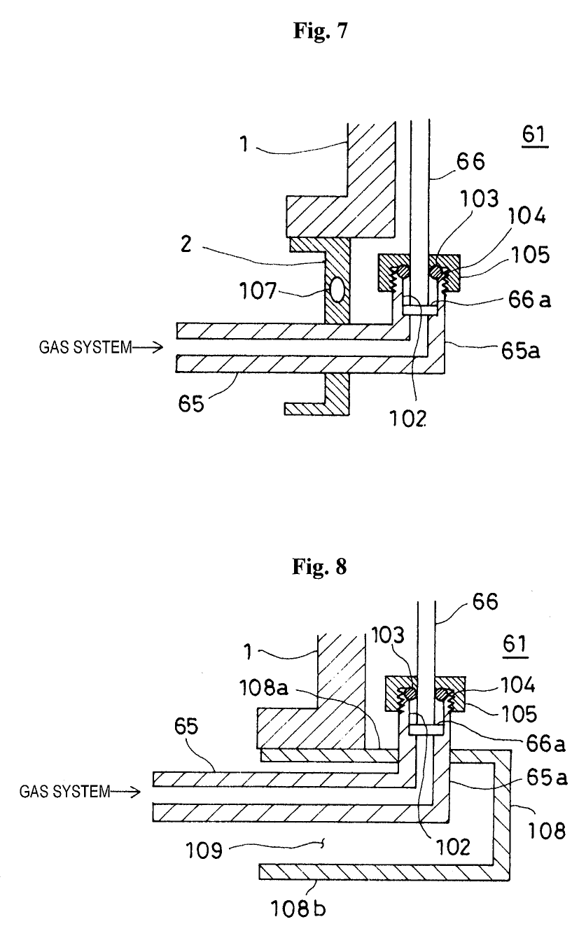

Next, a third embodiment of the present invention will be described with reference to FIG. 7.

In the third embodiment as compared with the first embodiment, a ring-shaped coolant circulation passage 107 is formed in the wall of the manifold 2 in a circumferential direction.

The coolant circulation passage 107 is installed on substantially the same plane where the connection part of the nozzle holder 65 and the gas supply nozzle 66 is located, and the coolant circulation passage 107 is connected to a coolant circulation device (not shown) through coolant supply and discharge pipes (not shown). A cooling mechanism is constituted by the coolant circulation passage 107, the coolant supply pipe, the coolant discharge pipe, and the coolant circulation device.

Like in the first embodiment, the gas supply nozzle 66 can be vertically held by inserting the gas supply nozzle 66 into the nozzle hold hole 102, and coupling the ring nut 105 to the inner end part 65a with the O-ring 103 being disposed therebetween.

During substrate treatment, process gas is supplied from the gas supply system to the nozzle holder 65, and the process gas is introduced into the process chamber 61 from the nozzle holder 65. Then, the process gas introduced into the process chamber 61 is discharged through the gas exhaust pipe 62 by the vacuum exhaust device 64.

In parallel with the substrate treatment, coolant such as cooling gas or cooling water is supplied to the coolant circulation passage 107 through the coolant supply pipe (not shown), and after the coolant circulates through the coolant circulation passage 107, the coolant is discharged through the coolant discharge pipe (not shown).

By circulating coolant in the coolant circulation passage 107, radiant heat from the inside of the process chamber 61 can be absorbed, and the connection part of the nozzle holder 65 and the gas supply nozzle 66 can be cooled for preventing overheating. Therefore, thermal load acting on the O-ring 103 can be reduced.

Next, a fourth embodiment of the present invention will be described with reference to FIG. 8.

In the fourth embodiment, a wall of a manifold 108 protrudes toward the inside of the process chamber 61, and the inner periphery of a top surface 108a of the manifold 108 extends from the inner wall of the reaction tube 1 toward the center of the process chamber 61. In addition, the manifold 108 has a [symbol] -shaped section, and a ring-shaped space is formed between the top surface 108a and a bottom surface 108b of the manifold 108.

The nozzle holder 65 is installed in the space 109, and the inner end part 65a is inserted upward through the top surface 108a of the manifold 108 protruded toward the inside of the process chamber 61. The inner end part 65a is air-tightly fixed to the top surface 108a by, for example, welding.

In the fourth embodiment, owing to the above-described structure, when process gas is supplied from the gas supply system 67 to the inside of the process chamber 61 through the nozzle holder 65, the process gas can be cooled by air of the space 109, and thus the nozzle holder 65 and the gas supply nozzle 66 can also be cooled by the cooled process gas. Therefore, the O-ring 103 used to connect the nozzle holder 65 and the gas supply nozzle 66 air-tightly can be less affected by thermal load. In addition, a device such as a fan may be used to blow air of the space 109 in order to increase cooling efficiency.

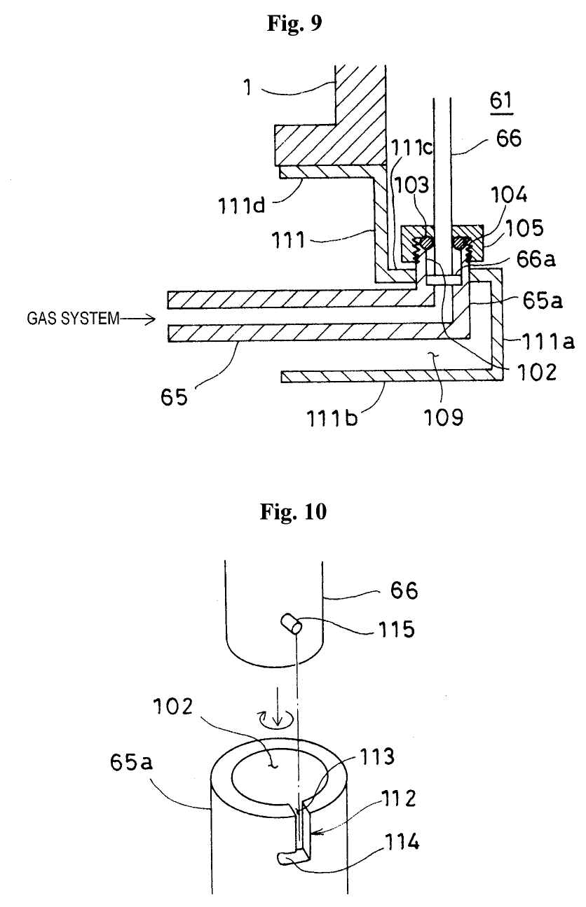

Next, a fifth embodiment of the present invention will be described with reference to FIG. 9.

The fifth embodiment is obtained by combining the first and fourth embodiments.

A lower part 111a of a wall of a manifold 111 is protruded toward the inside of the process chamber 61, and a top part 111c of the protruded lower part 111a is lower than an upper flange 111d of the manifold 111.

In addition, a space 109 is formed between the top part 111c and a lower flange 111b of the manifold 111, and the nozzle holder 65 is installed in the space 109. The inner end part 65a of the nozzle holder 65 is inserted through the top part 111c and air-tightly fixed to the top part 111c by, for example, welding.

In addition, the connection part of the nozzle holder 65 and the gas supply nozzle 66 is lower than the lower end of the reaction tube 1 and the lower end of the heater 58 installed around the reaction tube 1.

In the fifth embodiment, owing to the above-described structure, when process gas is supplied from the gas supply system 67 to the inside of the process chamber 61 through the nozzle holder 65, the process gas can be cooled by air of the space 109. Furthermore, since the connection part of the nozzle holder 65 and the gas supply nozzle 66 is lower than the heater 58, direct heat transfer from the heater 58 to the connection part can be prevented, and thermal load acting on the O-ring 103 can be reduced more than in the first and fourth embodiments.

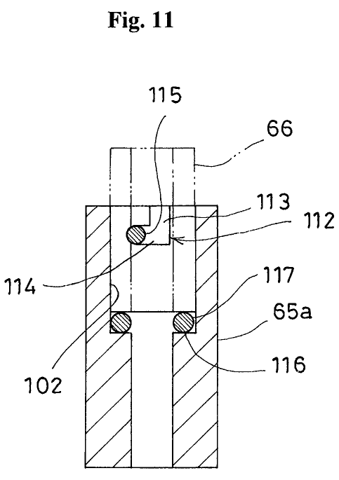

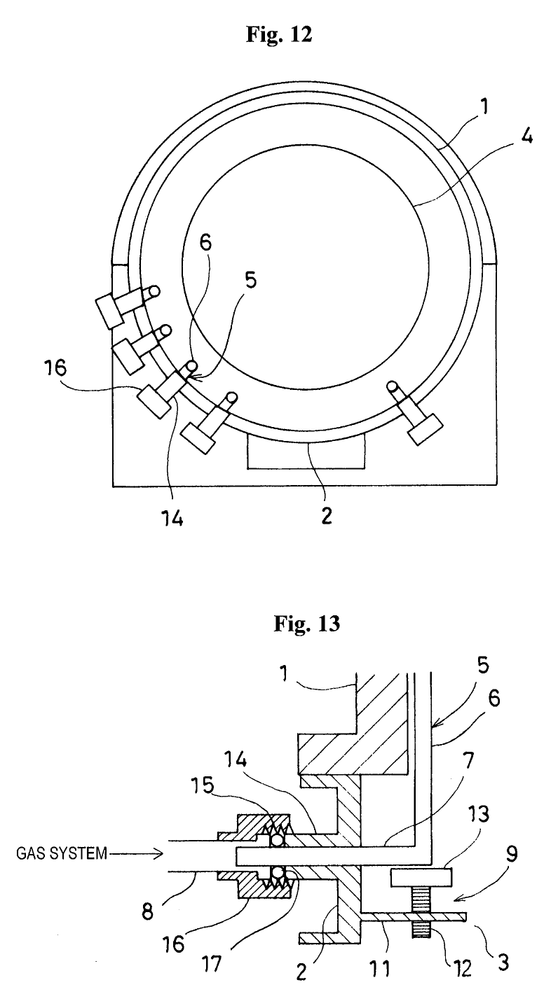

Next, a sixth embodiment of the present invention will be described with reference to FIG. 10 and FIG. 11.

In the sixth embodiment, a connection structure of the nozzle holder 65 and the gas supply nozzle 66 is described.

The nozzle hold hole 102 is bored in the inner end part 65a of the nozzle holder 65 from the top side of the inner end part 65a, in a manner such that the nozzle hold hole 102 is coaxial with the inner end part 65a. A stepped part 116 is formed at the bottom side of the nozzle hold hole 102, and an O-ring 117 is installed on the top surface of the stepped part 116.

At the leading end of the inner end part 65a, an L-shaped latch slit 112 is bored. The latch slit 112 includes a pin insertion slit 113 bored in a vertical direction, and a pin latch slit 114 bored continuously from the lower end of the pin insertion slit 113 in a horizontal or substantially horizontal direction. The pin latch slit 114 has the same width as the pin insertion slit 113.

The outer diameter of the gas supply nozzle 66 is substantially the same as the inner diameter of the inner end part 65a, and a latch pin 115 is installed on the outer surface of the gas supply nozzle 66. The diameter of the latch pin 115 is substantially the same as the width of the pin insertion slit 113 and the pin latch slit 114. The length of the latch pin 115 is substantially the same as the pipe thickness of the inner end part 65a.

By inserting the gas supply nozzle 66 into the nozzle hold hole 102 in a manner such that the latch pin 115 passes through the pin insertion slit 113, the lower end of the gas supply nozzle 66 can be placed against the O-ring 117. Therefore, the vertical position of the gas supply nozzle 66 is determined, and at the time, the radial (horizontal) position of the gas supply nozzle 66 is determined by the fitting of the gas supply nozzle 66 and the nozzle hold hole 102. In addition, since the gas supply nozzle 66 is fitted into the nozzle hold hole 102, the gas supply nozzle 66 can be held in a vertical posture.

At this time, the latch pin 115 is placed slightly above the pin latch slit 114, and thus the latch pin 115 can be fitted into the pin latch slit 114 by pushing the gas supply nozzle 66 to align the latch pin 115 with the pin latch slit 114 and rotating the gas supply nozzle 66.

Owing to the above-described operation, the O-ring 117 can be compressed between the stepped part 116 and the lower end of the gas supply nozzle 66, and thus the nozzle holder 65 and the gas supply nozzle 66 can be air-tightly connected.

In the first to fifth embodiments, the gas supply nozzle 66 is attached to the nozzle holder 65 only by inserting the gas supply nozzle 66 into the nozzle hold hole 102 and fastening the ring nut 105. In the sixth embodiment, the gas supply nozzle 66 is attached to the nozzle holder 65 only by inserting the gas supply nozzle 66 into the nozzle hold hole 102. Therefore, the gas supply nozzle 66 made of a material such as quartz can be attached with no unnecessary adjustment, no influence by the skill of an operator, high attachment precision, and high repeatability.

In addition, the gas supply nozzle 66 can be simply replaced by inserting/removing the gas supply nozzle 66 into/from the opening of the nozzle holder 65, and thus accidents such as breakage of a quartz nozzle can be prevented.

(Supplementary Note)

The present invention also includes the following embodiments.

(Supplementary Note 1)

According to an embodiment of the present invention, there is provided a substrate processing apparatus comprising: a process chamber configured to accommodate substrates in a stacked manner; a heating unit configured to heat an inside of the process chamber to a predetermined temperature; a gas supply unit configured to supply predetermined process gas to the inside of the process chamber; and an exhaust unit configured to exhaust the inside of the process chamber, wherein the gas supply unit comprises: a gas supply nozzle having a straight pipe shape and installed in a stacked direction of the substrates; a metal pipe configured to support the gas supply nozzle; and a manifold forming a lower part of the process chamber, wherein the metal pipe comprises: a first part extending from an outside of the process chamber to the inside of the processes chamber through the manifold; and a second part connected to the first part and extending in the stacked direction of the substrates, wherein the gas supply nozzle is fitted to the second part and supported by the second part. Therefore, the connection part between the gas supply nozzle and the metal pipe can be placed inside the process chamber, and process gas can be exhausted from the inside of the process chamber using the exhaust unit without the possibility of leakage of the process gas to the outside of the process chamber. In addition, since the gas supply nozzle is fixed to and supported by the second part, the horizontal and vertical positions of the gas supply nozzle can also be fixed, so that work efficiency can be improved, and work load on an operator can be reduced because the necessary level of skill is low.

(Supplementary Note 2)

The substrate processing apparatus of Supplementary Note 1 may further comprise a heat shield plate installed above a fitting part between the gas supply nozzle and the second part. In this case, the fitting part is not directly heated by heat transferred from the inside of the process chamber.

(Supplementary Note 3)

In the substrate processing apparatus of Supplementary Note 1, a ring-shaped hole may be bored in a wall of the manifold at substantially the same height as a fitting part between the gas supply nozzle and the second part, and a cooling mechanism may be installed at the hole for circulating a coolant. In this case, the fitting part can be cooled using the coolant for preventing overheating of the fitting part.

(Supplementary Note 4)

In the substrate processing apparatus of Supplementary Note 1, the manifold may comprise a protruded part formed by recessing the manifold toward a center of the process chamber, wherein the protruded part may extend to the inside of the process chamber so that the second part extends from the outside of the process chamber to the inside of the process chamber through a top surface of the protruded part. In this case, process gas can be cooled while flowing through the first part, and thus the fitting part between the gas supply nozzle and the second part can be cooled by the cooled process gas.

(Supplementary Note 5)

In the substrate processing apparatus of Supplementary Note 1, the manifold may comprise a protruded part formed by recessing the manifold toward a center of the process chamber, wherein the protruded part may extend to the inside of the process chamber so that: a top surface of the protruded part is lower than a top surface of the manifold; the second part penetrates the top surface of the protruded part from the outside of the process chamber; and a fitting part between the gas supply nozzle and the second part is lower than the heating unit. In this case, process gas can be cooled while flowing through the first part, and thus the fitting part between the gas supply nozzle and the second part can be cooled by the cooled process gas. In addition, the fitting part can be prevented from being directly heated by the heating unit.

(Supplementary Note 6)

In the substrate processing apparatus of Supplementary Note 1, the gas supply nozzle may be fitted to the second part by forming a longitudinal silt from a top end of the second part in a vertical direction, forming a transverse slit having the same width as that of the longitudinal slit from a lower end of the longitudinal slit in a horizontal direction, forming a protrusion on a wall of the gas supply nozzle, and fitting the protrusion into the transverse slit. In this case, the number of parts necessary for connecting the gas supply nozzle to the second part can be reduced, and the gas supply nozzle and the second part can be connected to each other with less manpower.

What is claimed is:

1. A substrate processing apparatus comprising:
a process chamber configured to accommodate substrates in a stacked manner;
a heating unit configured to heat an inside of the process chamber to a predetermined temperature;
a gas supply unit configured to supply predetermined process gas to the inside of the process chamber; and
an exhaust unit configured to exhaust the inside of the process chamber,
wherein the gas supply unit comprises:
a gas supply nozzle having a straight pipe shape and installed in a stacked direction of the substrates;
a metal pipe configured to support the gas supply nozzle; and
a manifold forming a lower part of the process chamber,
wherein the metal pipe comprises:
a first part extending from an outside of the process chamber to the inside of the processes chamber through the manifold; and
a second part connected to the first part and extending in the stacked direction of the substrates,
wherein the gas supply nozzle is fitted to the second part and supported by the second part.

2. The substrate processing apparatus of claim 1, further comprising a heat shield plate installed above a fitting part between the gas supply nozzle and the second part.

3. The substrate processing apparatus of claim 1, wherein a ring-shaped hole is bored in a wall of the manifold at substantially the same height as a fitting part between the gas supply nozzle and the second part, and a cooling mechanism is installed at the hole for circulating a coolant.

4. The substrate processing apparatus of claim 1, wherein the manifold comprises a protruded part formed by recessing the manifold toward a center of the process chamber,
wherein the protruded part extends to the inside of the process chamber so that the second part extends from the outside of the process chamber to the inside of the process chamber through a top surface of the protruded part.

5. The substrate processing apparatus of claim 1, wherein the manifold comprises a protruded part formed by recessing the manifold toward a center of the process chamber,
wherein the protruded part extends to the inside of the process chamber so that: a top surface of the protruded part is lower than a top surface of the manifold; the second part penetrates the top surface of the protruded part from the outside of the process chamber; and a fitting part between the gas supply nozzle and the second part is lower than the heating unit.

6. The substrate processing apparatus of claim 1, wherein the gas supply nozzle is fitted to the second part by forming a longitudinal silt from a top end of the second part in a vertical direction, forming a transverse slit having the same width as that of the longitudinal slit from a lower end of the longitudinal slit in a horizontal direction, forming a protrusion on a wall of the gas supply nozzle, and fitting the protrusion into the transverse slit.
